(19) United States
(12) Patent Application Publication
(10) Pub. No.: US 2013/0015056 A1
(43) Pub. Date: Jan. 17, 2013

(54) DEPOSITION SYSTEM HAVING IMPROVED TARGET COOLING

(71) Applicant: George X. Guo, Palo Alto, CA (US)

(72) Inventor: George X. Guo, Palo Alto, CA (US)

(21) Appl. No.: 13/183,781

(22) Filed: Jul. 15, 2011

(51) Int. Cl. C23C 14/34; C23C 14/14; C23C 14/08; C23C 14/06; C23C 14/35

(52) U.S. Cl. 204/192.15; 204/298.09; 204/192.12

(57) ABSTRACT

A vacuum processing system includes a vacuum chamber that can contain a workpiece therein, a deposition source unit that provides a material to be deposited on the workpiece in vacuum, and a cooling module in thermal contact with the deposition source unit. The cooling module includes one or more holding wells that can contain a cooling liquid. The cooling module can cool the deposition source unit by a loss of latent heat during the evaporation of the cooling liquid.

### BACKGROUND OF THE INVENTION

The present application relates to technologies for cooling targets in vacuum deposition systems.

Material deposition is widely used in window glass coating, light emitting diode (LED), circuit boards, flat panel display manufacturing, coating on flexible films (such as webs), hard disk coating, industrial surface coating, semiconductor wafer processing, photovoltaic panels, and other applications.

Referring to FIGS. 1A and 1B, a conventional vacuum deposition system 100 includes a vacuum chamber 110, a workpiece holder 120 configured to hold a workpiece 130, a target 150, and a backing plate 160. The backing plate includes a tunnel 170 having an inlet 171 and outlet 172. In deposition operation, the target 150 is usually heated up by sputtering, which can be cooled by a coolant through tunnels 170 through the backing plate 160. The coolant needs to be actively cooled by a chiller.

The conventional vacuum deposition system has several drawbacks. Some target materials (such as Sn, In) have low melting temperatures or low sublimation temperatures (such as Se, S, etc.), heating induced by sputtering can create unwanted, uncontrolled melting or evaporation of the target materials, which cannot be effectively prevented by conventional cooling methods.

Additionally, a large pressure is needed to force the coolant to cool the target, which increases the pressure differential already exerted on the backing plate by the atmospheric pressure versus the vacuum in the vacuum chamber 110. The pressure difference on the two sides of the assembly of the target 150 and the backing plate 160 causes the target 150 and the backing plate 160 to bend, which often causes the target 150 to crack and delaminate from the backing plate 160.

There is therefore a need to provide a simpler and more effective target cooling, especially for target materials having low melting or sublimation temperatures.

### SUMMARY OF THE INVENTION

The present invention can overcome aforementioned deficiencies. The present invention can provide faster and more effective cooling to target materials in vacuum deposition systems. As a result, targets can be kept much below room temperature during material deposition, which allows sputtering of Selenium, Indium, and other low melting temperature materials without evaporation caused by sputtering heating.

The presently disclosed systems eliminate the circulating tunnels in the backing plate in some conventional systems, and are thus simpler and of lower cost than some conventional systems.

Furthermore, the presently disclosed systems and methods consume less energy to operate than some conventional systems.

Moreover, the presently disclosed systems can further prevent the target material from cracking and delamination because the invention system does not use forced coolant to cool the target.

In one general aspect, the present invention relates to a vacuum processing system that includes a vacuum chamber that can contain a workpiece therein, a deposition source unit that provides a material to be deposited on the workpiece in vacuum, and a cooling module in thermal contact with the deposition source unit. The cooling module includes one or more holding wells that can contain a cooling liquid. The cooling module can cool the deposition source unit by a loss of latent heat during the evaporation of the cooling liquid.

Implementations of the system may include one or more of the following. The deposition source unit can include a solid target material configured to be sputtered on to the workpiece by physical vapor deposition. The solid target material can include Au, Cu, Ta, Al, Ti, TiW, Ni, NiV, Sn, In, Se, CuGa, CuIn, CuGaSe, CuInSe, InSe, CdTe, CdS, ITO, ZnO, or ZnAlO. The cooling liquid can include water, alcohol, or liquid nitrogen. The vacuum processing system can further include a backing plate in thermal contact with the deposition source unit and the cooling module, wherein the backing plate provides mechanical support to the deposition source unit. The cooling liquid can be water, and the deposition source unit is maintained at below 100° C. The vacuum processing system can further include a fan configured to generate air circulation above the surface of the cooling liquid to accelerate the evaporation of the cooling liquid. The cooling liquid can be water, and the deposition source unit is maintained at between about 30° C. and about 80° C. The cooling module can include a cover configured to enclose the cooling module, wherein the vapor of the cooling liquid is exhausted from the cooling module. The cooling liquid can be water, and the deposition source unit is maintained at between about 5° C. and about 100° C.

In another general aspect, the present invention relates to a method for depositing material in a vacuum environment. The method includes placing a workpiece in a vacuum chamber which contains a deposition source unit a cooling module therein, wherein the cooling module is in thermal contact with the deposition source unit; introducing a cooling liquid in the cooling module; depositing a material from the deposition source unit on to the workpiece in vacuum; and allowing the cooling liquid to evaporate to cool the deposition source unit by the loss of latent heat during the evaporation of the cooling liquid.

Implementations of the system may include one or more of the following. The deposition source unit can include one or more holding wells configured to contain the cooling liquid. The deposition source unit is mechanically supported by a backing plate that is in thermal contact with the deposition source unit and the cooling module. The cooling liquid can be water, and the method further includes keeping the deposition source unit at below 100° C. The method can further include generating air circulation by a fan to above the surface of the cooling liquid to accelerate the evaporation of the cooling liquid. The cooling liquid can be water, and the method further includes keeping the deposition source unit at between about 30° C. and about 80° C. The cooling module can include a cover configured to enclose the cooling module, the method further including exhausting the vapor of the cooling liquid from the cooling module. The cooling liquid can be water, and the method further includes keeping the deposition source unit at between about 5° C. and about 100° C.

The details of one or more embodiments are set forth in the accompanying drawings and in the description below. Other features, objects, and advantages of the invention will become apparent from the description and drawings, and from the claims.

### BRIEF DESCRIPTION OF THE DRAWINGS

FIGS. 1A and 1B are respectively cross-sectional and perspective views of a conventional vacuum processing system.

FIGS. 2A and 2B are respectively cross-sectional and perspective views of a vacuum processing system providing effective cooling and heating in accordance with the present invention.

FIG. 3 is a cross-sectional view of the vacuum processing system FIGS. 2A and 2B with an additional air circulation to assist the evaporation of the liquid and thus the cooling of the target.

FIGS. 4A and 4B are respectively cross-sectional and perspective views of a vacuum processing system providing effective cooling and heating in accordance with another embodiment of the present invention.

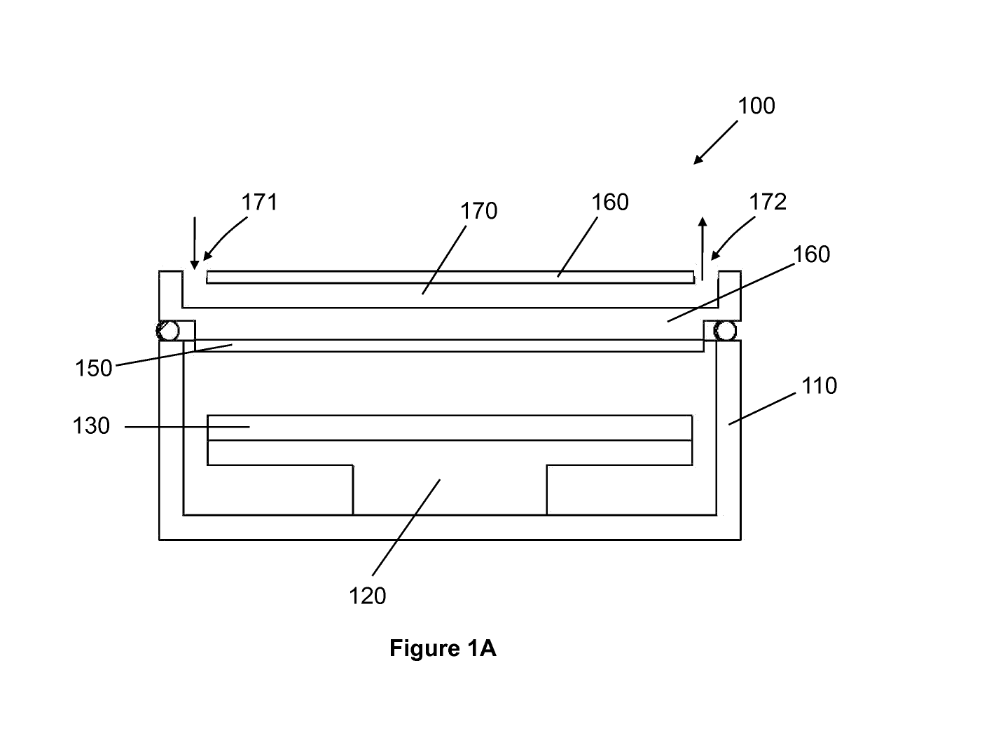

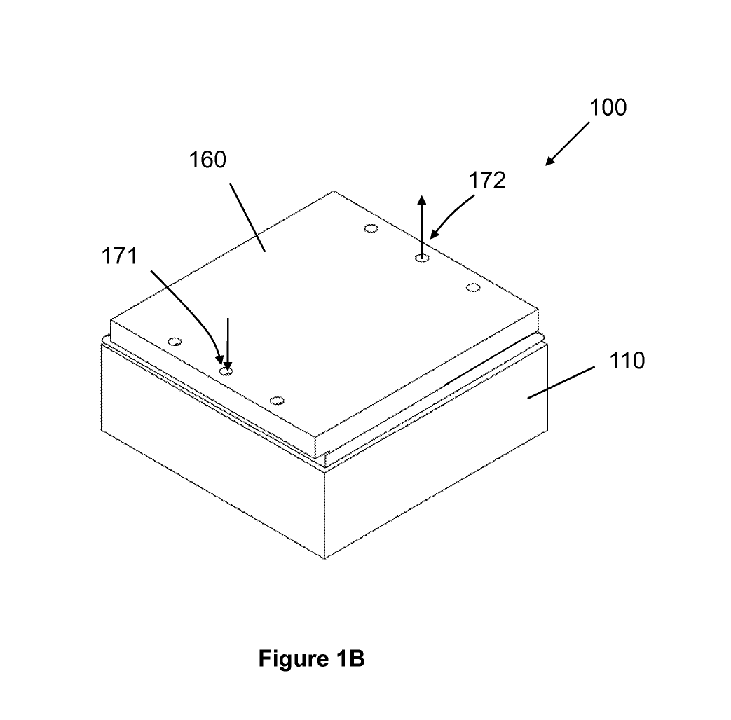

### DETAILED DESCRIPTION OF THE INVENTION

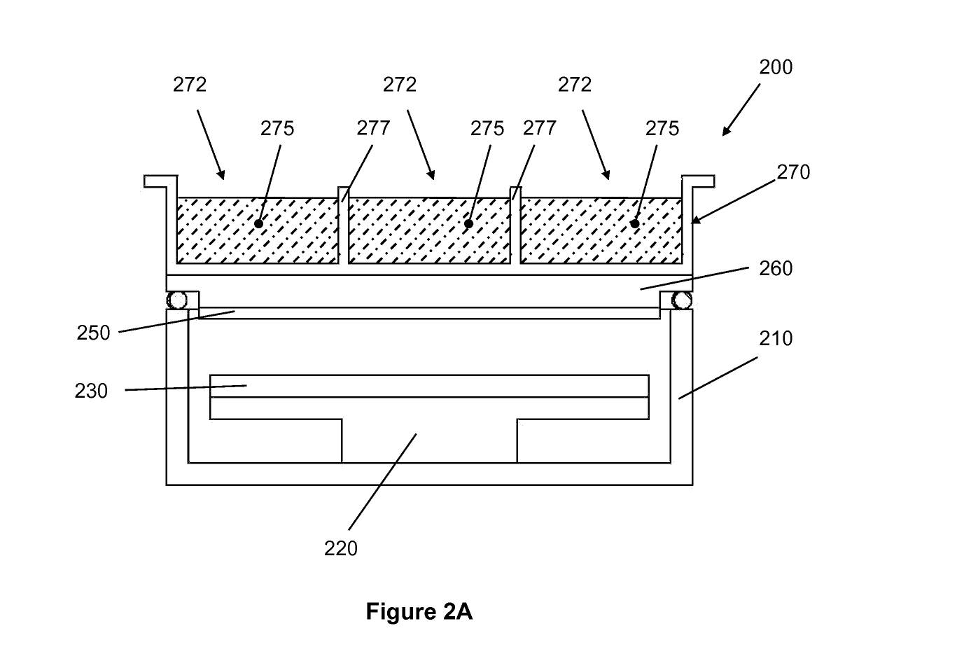

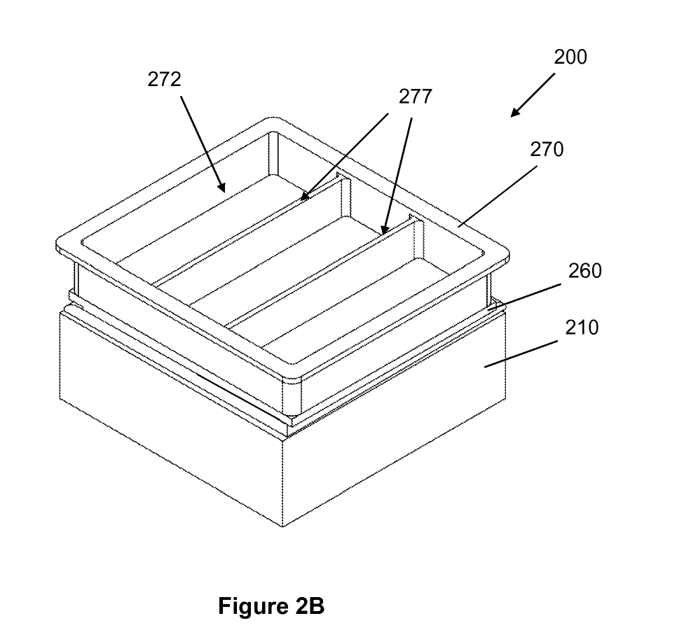

Referring to FIGS. 2A and 2B, a vacuum deposition system 200 includes a vacuum chamber 210, a workpiece holder 220 configured to hold a workpiece 230, a target 250, a backing plate 260 providing mechanical support to the target 250, and a cooling module 270. The backing plate 260 is made of a thermal conductive material such as copper, and is in good thermal contact with the target 250 and the cooling module 270. The cooling module 270 and the backing plate 260 can be a unitary component made from the same piece of the material. The workpiece can be a silicon wafer, a glass substrate, stainless steel web, GaAs substrate, etc.

The vacuum deposition system 200 can perform physical vapor deposition (PVD) which is a common technique in micro fabrication. The target 250 comprises a material to be sputtered by the magnetron-sputtering source 260 and deposited onto the workpiece 230. The deposition system 200 can also include a magnetron (not shown).

In material deposition, the process chamber 210 is pumped down to a reduced pressure. The workpiece holder 220 can be moved to achieve uniform deposition. The presently disclosed invention can be compatible with other arrangements for the target, the substrate, and transport mechanisms. For example, the target can in general be replaced by a deposition source unit, which can provide deposition materials in PVD, thermal evaporation, thermal sublimation, sputtering, chemical vapor deposition (CVD), and plasma enhanced chemical vapor deposition (PECVD). Details of a suitable deposition system are disclosed in the commonly assigned U.S. patent application Ser. No. 11/847,956, entitled “Substrate processing system having improved substrate transport system”, filed Aug. 30, 2007, the disclosure of which is disclosed herein by reference.

In deposition operation, a lot of heat can be generated by sputtering at the surface of the target 250. The target 250 can be made of solid materials such as Au, Cu, Ta, Al, Ti, TiW, Ni, NiV, Sn, In, Se, CuGa, CuIn, CuGaSe, CuInSe, InSe, CdTe, CdS, ITO, ZnO, or ZnAlO, etc. Some target materials such as In and Sn have low melting or low sublimation temperatures, it is important to keep targets made of these materials cooled at low temperature to prevent unwanted evaporation or sublimation during sputtering deposition. In the vacuum deposition system 200, the target 250 is cooled by the cooling module 270 through the backing plate 260.

The cooling module 270 includes one or more holding wells 272 for containing a cooling liquid 275 such as water, alcohol, liquid nitrogen. The holding wells 272 are positioned outside of the vacuum chamber 210 and facing upwards to receive and hold a cooling liquid 275. Optionally, the holding wells 272 can be separated by ribs 277 that can have holes to allow the cooling liquid 275 to flow between the holding wells 272. For large target sizes, the ribs 277 can provide mechanical strength to prevent the cooling module 270 from bending and buckling under the vacuum pressure and the weight of the deposition material and the cooling liquid 275, which can prevent the target material from cracking and delamination.

The holding wells 272 can be formed in the cooling module 270. Alternatively, the cooling device can have an open bottom such that backing plate 260 forms the bottom of the holding wells 272. The cooling liquid 275 can be in direct contact with the backing plate 260.

The cooling liquid 275 is poured into the holding wells 272 before and/or during material sputtering and deposition. The heat generated by sputtering can boil cooling liquid 275, and can cause the cooling liquid 275 to evaporate. The evaporation of the cooling liquid 275 also creates circulation in the cooling liquid 275 contained in the holding well 272. The latent heat carried away by the evaporated molecules cools the backing plate 260 and the target 250.

Unlike conventional system, the vacuum deposition system 200 does not require active power to circulate the cooling liquid 275 through the cooling module 270. The holding wells 272 are in the ambient environment and easily accessible. When needed, more cooling liquid 275 can be added to the holding well 272 during deposition. Using water as the cooling liquid 272, the target temperature can maintained at below the boiling temperature of 100° C. The elimination of the cooling tunnels also significantly simplifies the making and the cost of the backing plate.

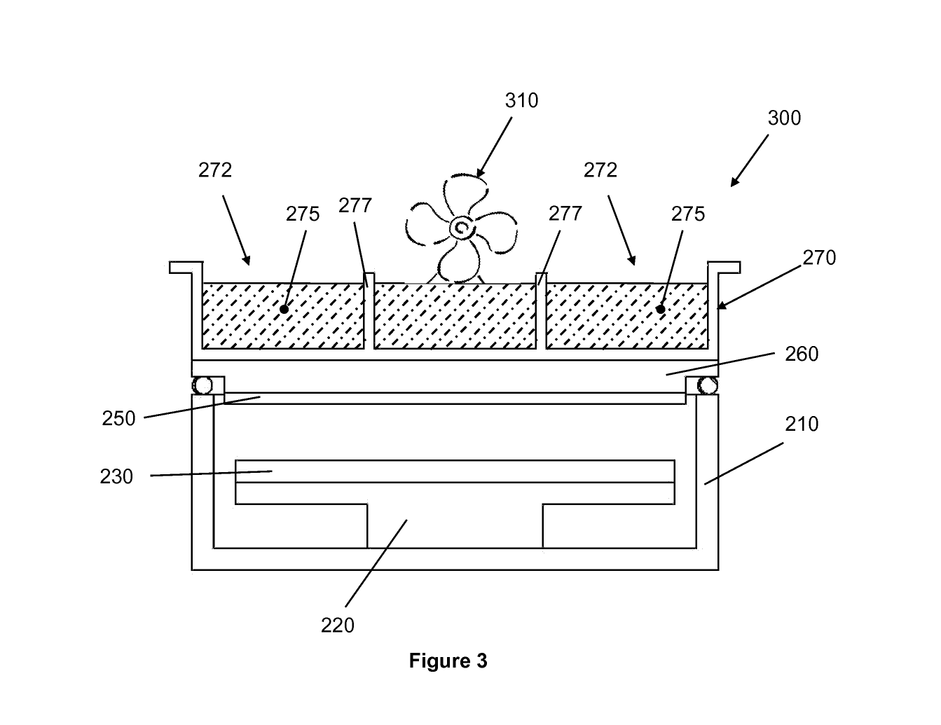

In some embodiments, referring to a vacuum deposition system 300 in FIG. 3, the evaporation of the cooling liquid 275 can be made more effective by blowing air with a fan 310 across the surfaces of the cooling liquid 275 in the cooling wells 272. The evaporated vapor and heat can be quickly removed from the surfaces of the cooling liquid 275. Using water as the cooling liquid 272, the target temperature can be maintained between about 30° C. and about 80° C.

It should be noted that the power consumes to blow air in the vacuum deposition system 300 is much lower than the power needed to actively cool the coolant through a chiller and pump cooling fluid through the backing plate in some conventional systems.

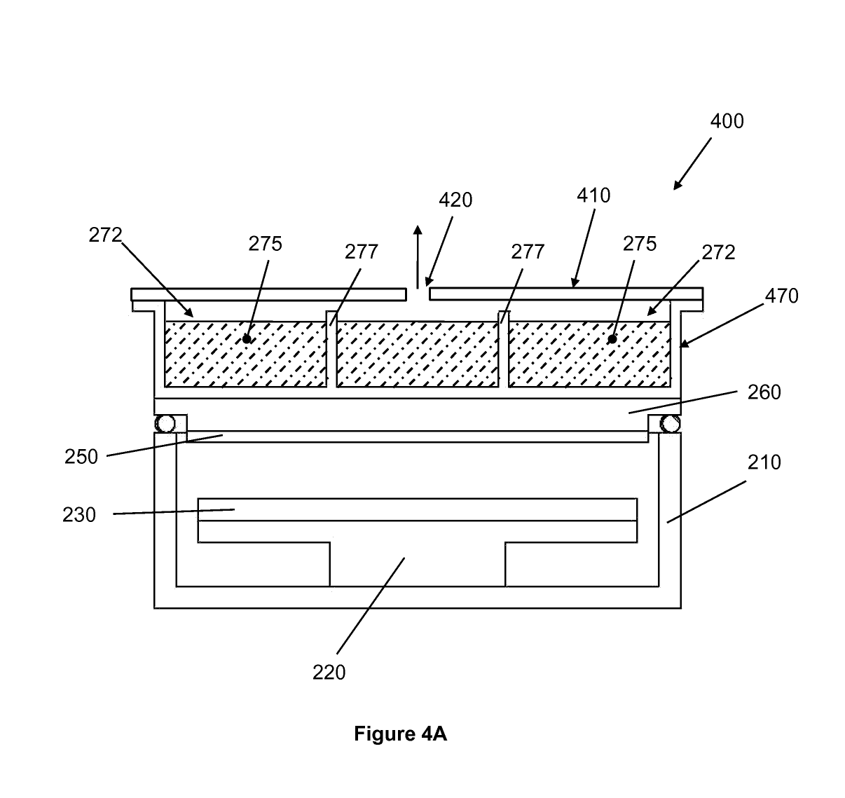

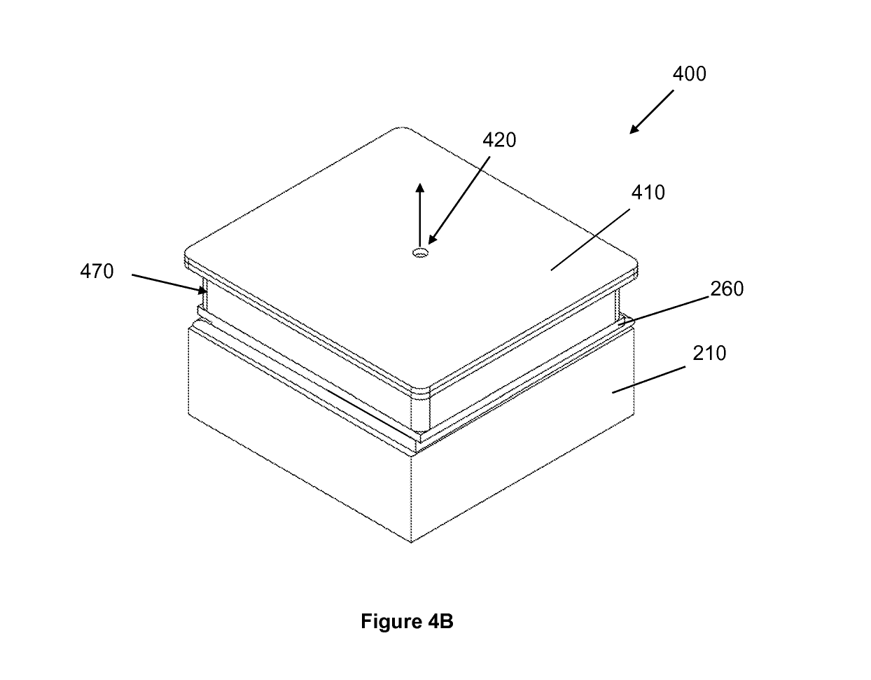

In some embodiments, referring to a vacuum deposition system 400 in FIGS. 4A and 4B, the opening of the holding wells 272 can be enclosed by a cover 410 to form an enclosed cooling module 470. The cover 410 includes an opening 420. Vapor of the cooling liquid 275 generated during material deposition can be exhausted of the enclosed cooling module 470 by a vacuum pump (not shown). The air/vapor pressure in the enclosed cooling module 470 can be maintained below 1 atmosphere, for example, at about 0.5 atmospheres. The advantage of the vacuum deposition system 400 is that the cooling efficiency can be controlled by the exhaustion of the vapor from the enclosed cooling module 470. Using water as the cooling liquid 272, the target temperature can be controlled in a range between 0° C. and 100° C., such as between 5° C. and 100° C.

It is understood that the disclosed systems are compatible with many different types of processing operations such as PVD, thermal evaporation, thermal sublimation, sputtering, CVD, PECVD, ion etching, or sputter etching. The disclosed processing systems can include other components such as load lock, transport mechanism for the substrates, etc. without deviating from the spirit of the invention. The deposition materials can be provided by sputtering targets, gas distribution device, and other types of source units without deviating from the spirit of the invention.

What is claimed is:

1. A vacuum processing system, comprising:
a vacuum chamber configured to contain a workpiece therein;
a deposition source unit configured to provide a material to be deposited on the workpiece in vacuum; and
a cooling module in thermal contact with the deposition source unit, wherein the cooling module includes one or more holding wells configured to contain a cooling liquid, wherein the cooling module is configured to cool the deposition source unit by a loss of latent heat during the evaporation of the cooling liquid.

2. The vacuum processing system of claim 1, wherein the deposition source unit comprises a solid target material configured to be sputtered on to the workpiece by physical vapor deposition.

3. The vacuum processing system of claim 2, wherein the solid target material comprises Au, Cu, Ta, Al, Ti, TiW, Ni, NiV, Sn, In, Se, CuGa, CuIn, CuGaSe, CuInSe, InSe, CdTe, CdS, ITO, ZnO, or ZnAlO.

4. The vacuum processing system of claim 1, wherein the cooling liquid includes water, alcohol, or liquid nitrogen.

5. The vacuum processing system of claim 1, further comprising:
a backing plate in thermal contact with the deposition source unit and the cooling module, wherein the backing plate provides mechanical support to the deposition source unit.

6. The vacuum processing system of claim 1, wherein the cooling liquid is water, and wherein the deposition source unit is maintained at below 100° C.

7. The vacuum processing system of claim 1, further comprising:
a fan configured to generate air circulation above the surface of the cooling liquid to accelerate the evaporation of the cooling liquid.

8. The vacuum processing system of claim 7, wherein the cooling liquid is water, and wherein the deposition source unit is maintained at between about 30° C. and about 80° C.

9. The vacuum processing system of claim 1, wherein the cooling module comprises a cover configured to enclose the cooling module, wherein the vapor of the cooling liquid is exhausted from the cooling module.

10. The vacuum processing system of claim 9, wherein the cooling liquid is water, and wherein the deposition source unit is maintained at between about 5° C. and about 100° C.

11. A method for depositing material in a vacuum environment, comprising:
placing a workpiece in a vacuum chamber which contains a deposition source unit a cooling module therein, wherein the cooling module is in thermal contact with the deposition source unit;
introducing a cooling liquid in the cooling module;
depositing a material from the deposition source unit on to the workpiece in vacuum; and
allowing the cooling liquid to evaporate to cool the deposition source unit by the loss of latent heat during the evaporation of the cooling liquid.

12. The method of claim 11, wherein the deposition source unit includes one or more holding wells configured to contain the cooling liquid.

13. The method of claim 11, wherein the deposition source unit is mechanically supported by a backing plate that is in thermal contact with the deposition source unit and the cooling module.

14. The method of claim 11, wherein the deposition source unit comprises Au, Cu, Ta, Al, Ti, TiW, Ni, NiV, Sn, In, Se, CuGa, CuIn, CuGaSe, CuInSe, InSe, CdTe, CdS, ITO, ZnO, or ZnAlO.

15. The method of claim 11, wherein the cooling liquid includes water, alcohol, or liquid nitrogen.

16. The method of claim 11, wherein the cooling liquid is water, and wherein the deposition source unit is maintained at below 100° C.

17. The method of claim 11, further comprising:
generating air circulation by a fan to above the surface of the cooling liquid to accelerate the evaporation of the cooling liquid.

18. The method of claim 17, wherein the cooling liquid is water, the method further comprising:
keeping the deposition source unit at between about 30° C. and about 80° C.

19. The method of claim 11, wherein the cooling module comprises a cover configured to enclose the cooling module, the method further comprising:
exhausting the vapor of the cooling liquid from the cooling module.

20. The method of claim 19, wherein the cooling liquid is water, the method further comprising:
keeping the deposition source unit at between about 5° C. and about 100° C.
